(19) United States
(12) Patent Application Publication
(10) Pub. No.: US 2025/0386492 A1
(43) Pub. Date: Dec. 18, 2025

(54) GRADED CHANNEL DEVICES FOR NOR FLASH CELL ARRAY AND METHOD OF FABRICATING THE SAME

(71) Applicant: FlashSilicon Incorporation, Diamond Bar, CA (US)

(72) Inventors: Lee WANG, Diamond Bar, CA (US); Dae Sub JUNG, Diamond Bar, CA (US); Shiang-Chyong LUO, Diamond Bar, CA (US)

(21) Appl. No.: 18/743,545

(22) Filed: Jun. 14, 2024

(51) Int. Cl. H10B 41/27; G11C 16/04; H10B 41/10; H10B 43/10; H10B 43/27

(52) U.S. Cl. CPC H10B 41/27; G11C 16/0483; H10B 41/10; H10B 43/10; H10B 43/27

(57) ABSTRACT

A NOR flash memory array is disclosed, comprising: multiple cells organized in rows and columns, each cell comprising a channel region, a charge storing material, a control gate, a source region and a drain region, the cells along a predefined direction being arranged in cell pairs such that each cell pair shares a common source region that is encircled by a source halo implant region. The source halo implant region has the same conductivity type as the substrate, and the source halo implant region has a higher impurity concentration than a drain side of the channel region. The invention enhances the ChiTel programming efficiency and improves the short channel margins for the gate lengths of memory cells less than 100 nm in NOR flash memory array.

### BACKGROUND OF THE INVENTION

### Field of the Invention

This invention relates to the graded channel MOSFET (Metal Oxide Semiconductor Field Effect Transistor) devices applied for NOR-type flash memory cell arrays. In particular, the graded channel MOSFET devices are applied for the memory cell devices in NOR-type flash memory array for enhancing the ChiTel (Channel induced Ternary electron) programming efficiency and improving short channel margins for the gate lengths of memory cell devices less than 100 nm.

### Description of the Related Art

Semiconductor Non-Volatile Memory (NVM), and particularly Electrically Erasable, Programmable Read-Only Memories (EEPROM), exhibit wide spread applicability in a range of electronic equipment from computers, to telecommunication hardware, to consumer appliances. In general, EEPROM serves a niche in the NVM space as a mechanism for storing firmware and data that can be kept even with power off and can be altered as needed.

Data is stored in an EEPROM device by modulating its threshold voltage (device on/off voltage) of the Metal-Oxide-Semiconductor Field Effect Transistor (MOSFET) through the injection of charge carriers into the charge-storage layer from the substrate of the MOSFET device. For example, with respect to an N-channel MOSFET device, an accumulation of electrons in the floating gate, or in a dielectric layer, or in nano-crystal particles above the FET (Field Effect Transistor) channel region, causes the MOSFET to exhibit a relatively high threshold voltage state.

Flash EEPROM may be regarded as a specifically configured EEPROM into cell array that may be erased only on a global or sector-by-sector basis. Flash NVM arrays are also categorized as NOR flash array (paired devices in parallel connections) and NAND flash array (numbers of devices in series connections) according to the configurations of the memory cell device connections in flash arrays. The conventional NOR flash array connects cell devices in parallel-connected pairs 10 in FIG. 1, where rows of common source electrodes of the paired cell devices 10 are connected to form multiple horizontal common source lines CS and columns of drain electrodes of the paired cell devices 10 are connected to form multiple vertical bitlines, respectively. As the cell device schematic for an “M×N” NOR flash array shown in FIG. 1, each wordline running in x-direction contains “M” NVM cells with the drain electrodes of the NOR cell pairs 10 vertically connected to form bitlines Bᵢ for i=1, . . . . M, and each bitline running in y-direction is attached with “N” drain electrodes of the NVM cells. The common source electrodes 11 of rows of NOR cell pairs 10 in the array are horizontally connected to form the common source lines CS. When a wordline is selected, the entire “M” NVM cells under the selected wordline are activated. On the other hand, the NVM cells under the un-selected wordlines in the array are electrically detached from the “M” metal bitlines. The electrical responses at the drain electrodes of the selected “M” NVM cells can be detected through their attached “M” metal bitlines. Since the electrical biases and signals are directly applied through the metal bitlines and metal contacts to drain electrodes of the selected NVM cell devices in NOR-type flash array, the random read access time is very fast in the range of hundred to tens nano-seconds. Due to the fast random read access capability NOR-type flash is usually applied for computer program code storage.

While scaling down NOR flash memory with advanced process technology nodes for better device performance and lower fabrication cost, NOR flash memory array has hit the most difficult technical road block below the 100 nm fabrication process technology nodes caused by the memory cell device punch-through issue while applied with the conventional CHEI (Channel Hot Electron Injection) programming scheme to write data into NVM cell devices. It is known that when the gate length of a cell device is shorten to a smaller gate length, the device source-drain punch-through voltage drops accordingly. A typical memory device punch-through voltage for a gate length below 100 nm is usually less than 3V, which is lower than the applied source-drain voltage bias difference (4V˜6V) for the CHEI programming scheme. The cell device punch-through issue prevents the memory device gate length to further shrink down below 100 nm fabricated with the advanced process technology nodes, although the minimum feature sizes for the process technology nodes have already been advancing to below 10 nm process technology nowadays.

To resolve the memory device gate length scaling issue below 100 nm for NOR flash array, a new programming scheme for the short channel length NVM devices disclosed in U.S. Pat. No. 9,082,490 B2 (the disclosure of which are incorporated herein by reference in its entirety) has applied to the N-type NVM devices with the minimum gate length=32 nm fabricated with 40 nm process technology provided by a foundry. Due to the dramatic orders of magnitude increase (˜several hundreds to ˜thousands) of the high-energy ternary electrons induced in the N-type NVM device's channel, the new programming scheme of the invention is called Channel induced Ternary Electron (ChiTel) programming scheme, hereinafter.

Referring to FIG. 2, the ChiTel programming scheme for a NVM device includes the following steps: (1) floating the source electrode 210; (2) applying a voltage bias (2V˜6V) to the drain electrode 220 and a ground voltage to the substrate 290; and (3) applying a positive voltage V_{CGH} to the control gate 250. The new ChiTel programming scheme applies no voltage bias to the source electrodes, i.e., floating source electrodes, and a relative low voltage (2V˜6V) to the drain electrode compared with the applied drain voltage in the conventional CHEI programming scheme. The programming current for ChiTel scheme consumes only about 1/10 of the programming current for the conventional CHEI programming scheme. Furthermore since there is no external electrical field generated by the differential voltage bias between the applied voltage drain electrode and the “floating” source electrode along the device channel, the device channel punch-through current induced by the external drain-source electrical field does not occur in the ChiTel programming scheme. When the drain electrode 220 is applied with a voltage (2V˜6V) with the source electrode 210 floating and a grounded P-substrate 290 for a short channel N-type MOSFET device 200 (gate length <100 nm), the junction depletion regions 221 (negative impurity ions in the P-substrate region) of the applied drain voltage in the grounded P-substrate extend from the zero-voltage biased junction depletion regions 221′ to connect with the floating-voltage source junction depletion regions 231 about 300 angstroms ˜800 angstroms below the device's silicon surface in the P-type substrate 290 as shown in FIG. 2. In the ChiTel programming process as illustrated in FIG. 2, when a positive voltage V_{CGH} is applied to the control gate 250 of N-type MOSFET device 200, the inverted surface channel electrons 201 near the source region 210 are injected to the surface channel electrical field to accelerate toward the drain junction region (i.e., the surface region near drain junction), where the secondary electrons 202 and holes 204 are generated by the energy transfers from the accelerated primary electrons. The most electrons (the primary channel inverted electrons 201 and the generated secondary electrons 202 with very small amount of other electrons) near the surface drain region 220 are collected by the positive voltage biased drain electrode, while the generated heavy holes 204 are accelerated toward the substrate 290 to facilitate the generations of the high energy ternary electrons 203. The high energy ternary electrons 203 are generated by the energy transfers from the heavy holes 204 accelerated in the electrical field provided by the fixed negative P-type impurity ion regions (221 and 230) in the P-type substrate 290. Where the high energy ternary electrons 203 gaining enough kinetic energy to overcome the tunneling oxide energy barrier (>3.2 ev) get injected into the charge storage materials 280 (floating gate, charge trapping dielectrics, or nano-crystal particles) above the silicon surface.

In this invention for the NOR flash memory scaling, we apply the graded channel MOSFET device designs with higher channel impurity concentrations near the source regions and lower channel impurity concentrations near the drain regions to enhance the ChiTel programming efficiency in conjunction with better short channel margins for the cell devices' gate length less than 100 nm in NOR flash memory arrays.

### SUMMARY OF THE INVENTION

To illustrate the mechanism of the graded channel MOSFET devices about how to improve the ChiTel programming efficiency and the short channel margin for the cell device with a short gate length less than 100 nm in NOR flash memory array, we show the cross-section view of a floating-gate NVM device 300 with a graded channel impurity profile in FIG. 3. It is well known that the higher P-type impurity concentration in ion region 310 forms a smaller depletion width near the source side of the channel region in the grounded P-type substrate 290 with no source voltage bias. When a large enough voltage (2V˜6V) is applied to the drain electrode 220, the drain depletion region 221 in the grounded P-substrate 290 is connected with the floating-voltage source depletion region 231 as illustrated in FIG. 3. Due to the smaller “floating” source junction depletion width for the higher impurity concentration in the source depletion region 231, the P-type impurity depletion boundary line 321 for the high impurity concentration near source side moves accordingly closer to the source junction line 330 from the original depletion boundary line 320 for the symmetrical source/drain low P-type impurity concentration as indicated in FIG. 3. It is well known according to the physics law (Gauss law) that the higher concentration of fixed negative impurity ions in the P-type depletion region generates a stronger electrical field for holes to be accelerated for the generation of the high energy ternary electrons. Therefore the generation of high energy ternary electrons for the high impurity concentration occur closer to the source side of the channel region than that for the symmetrical source/drain low P-type impurity concentration. On the other hand, since the moving electrons (the primary electrons 301, the secondary electrons 302) near the drain region 220 are almost driven by the horizontal drain electrical field to the positive voltage applied drain electrode, only very few electrons (the so-called lucky electrons about one of millions) near the drain region 220 get injected into the charge storage material 280 above the silicon drain surface. Along the channel region, usually the electron injection rate from near the source side to the storage material 280 is hundred times to thousand times higher than that from near the drain side to the storage material 280. Therefore when applied with the ChiTel programming scheme, the graded channel NVM devices with higher impurity concentrations near the source regions 210 have very high electron injection rate to the storage material 280. In term of ChiTel programming efficiency, the total consumed energy for putting a certain amount of electrons into the storage material 280 is much less for the graded channel NVM devices 300 with higher impurity concentrations near the source region 210 than that for the NVM devices with the symmetrical source/drain low impurity concentrations.

Meanwhile while the P-type impurity concentration near the source region 210 is higher than that near the drain region 220 along the channel region, the device punch-through breakdown voltage gets increased for the higher source junction impurity concentration and the drain junction leakage current gets decreased for the lower drain junction impurity concentration. The increase of device punch-through breakdown voltage has a better short channel margin for the NVM devices with gate length less than 100 nm in NOR flash memory arrays. The low device channel leakage current for a high device punch-through breakdown voltage and the low device drain junction leakage current for the low junction impurity concentration can further lead to a very low bitline leakage current generated by the connecting drain electrodes of a column of NVM devices in the NOR flash memory array when applying with the bitline voltage bias for the programming operation and read operations.

To create the asymmetrical source/drain channel impurity profiles for the N-type graded channel NVM devices 300, extra P-type impurity tilted halo implants with the mask openings in the source areas and implant dosage between 10¹² cm⁻²˜10¹⁴ cm⁻² are inserted after the control gate 250 and photoresist 420 formations in the NOR flash memory fabrication process flow. As illustrated in FIG. 4A, both the extra P-type impurity tilted halo implant 411 in the 0° direction (or −Y direction parallel to the gate length direction) for the right sided devices and the tilted halo implant 412 in the 180° (opposite) direction (or +Y direction parallel to the gate length direction) for the left sided devices with the blocking photoresist 420 openings in the common source areas are performed to form the P-type impurity implanted region (also called “source halo implant region”) 410. Note that the implant directions (0° and 180°) in the cross-section plan of FIG. 4A are vertical to common source areas inward/outward the cross-section plan, and that the P-type impurity tilted halo implants 411 and 412 are additional besides the traditional symmetrical source and drain extension/halo implants (with the same impurity concentrations) for short channel MOSFET devices 400. FIG. 4B shows a cross section view of two cell devices 400 having a common source extension region 210 and two drain extension regions 220 after the traditional symmetrical source and drain extension/halo implant formation according to FIG. 4A. Referring to FIG. 4B, the source halo implant region 410 encircles the common source extension region 210 while the drain halo implant regions 430 (formed by the traditional symmetrical source and drain extension/halo implant) encircles the drain N-type impurity extension region 220. The source halo implant region 410 has a P-type impurity concentration c1 higher than the background P-type impurity concentration c2 in the P-type substrate 290. In particular, the source halo implant region 410 has the P-type impurity concentration c1 higher than that c3 in the drain halo implant regions 430 so that: (1) the generated ternary electron injection rate occurring in the source halo implant region 410 to the storage material 280 is hundred times to thousand times higher than that occurring in the drain halo implant region 430 to the storage material 280 for the ChiTel programming; and (2) three different impurity concentrations distributed along the channel region 450 form a graded channel, where c1>c3>c2.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows a typical schematic for the conventional NOR-type flash memory array

FIG. 2 illustrates the programming mechanism for ChiTel scheme.

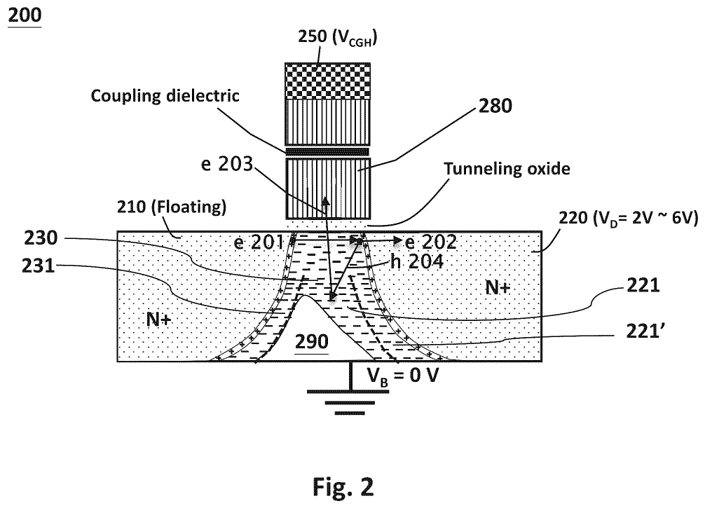

FIG. 3 shows the generation of high energy ternary electrons for a source side in a graded channel cell device by ChiTel programming scheme.

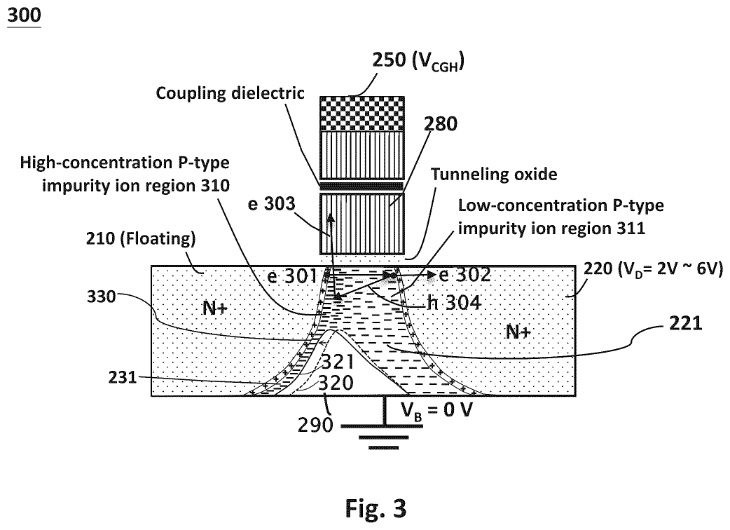

FIG. 4A shows two cell devices receive two extra P-type impurity tilted halo implants 411 and 412 in their common source area for the fabrication of graded channel devices in NOR flash memory array.

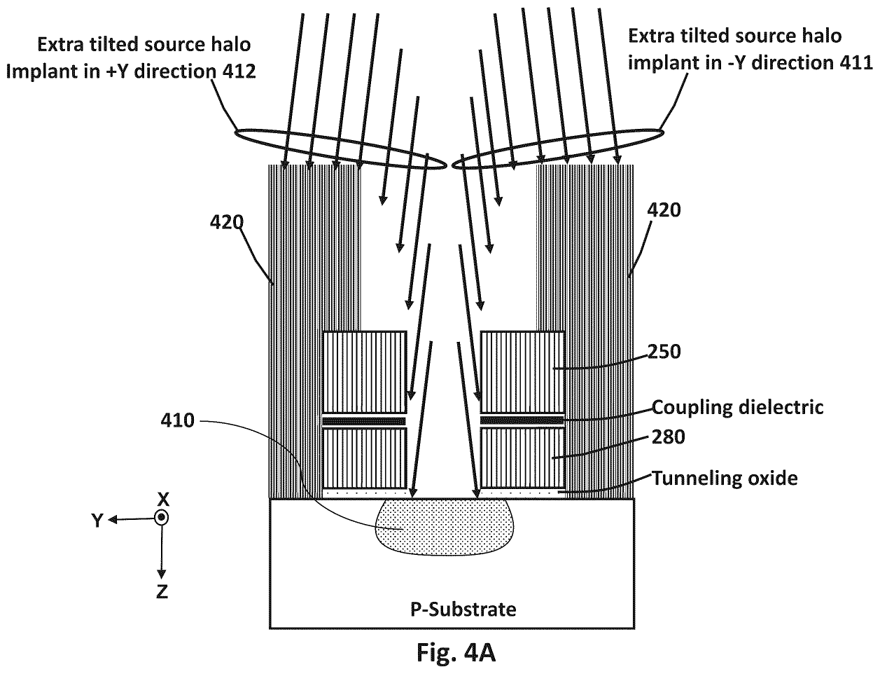

FIG. 4B shows a cross section view of two cell devices 400 having a common source region 210

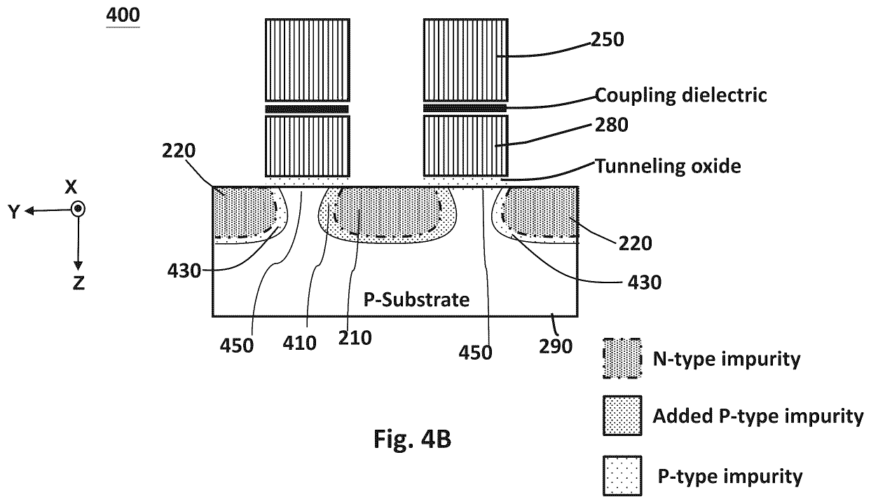

and two drain regions 220 after the source and drain extension formation according to FIG. 4A.

FIG. 5 shows the top view of the mask opening areas 580 for the extra tilted source halo implants in the NOR flash memory array according to one embodiment of this invention.

FIG. 6 shows the cross section view of two paired cell devices after the first extra tilted source halo implant for the NOR flash arrays of FIG. 1 according to one embodiment of this invention.

FIG. 7 shows the cross section view of two paired cell devices after a second extra tilted source halo implant and the first extra tilted source halo implant in FIG. 6 for the NOR flash arrays according to one embodiment of this invention.

FIG. 8A shows the schematics of the conventional field sub-bitline NOR flash memory array.

FIG. 8B shows a cross section view of a row of NVM devices in the conventional field sub-bitline NOR flash memory array in FIG. 8A.

FIG. 9 shows the top view of the mask opening areas 980 for the tilted source halo implants in the field sub-bitline NOR flash memory array of FIG. 8A according to another embodiment of this invention.

FIG. 10 shows the cross section view of paired NOR flash memory cell devices after the first extra tilted source halo implant for the field sub-bitline NOR flash arrays according to another embodiment of this invention.

FIG. 11 shows the cross section view of paired NOR flash memory cell devices after a second extra tilted source halo implant and the first extra tilted source halo implant in FIG. 10 for the field sub-bitline NOR flash arrays according to another embodiment of this invention.

### DETAILED DESCRIPTION OF THE INVENTION

The following detailed description is meant to be illustrative only and not limiting. It is to be understood that other embodiment may be utilized and element changes may be made without departing from the scope of the present invention. Also, it is to be understood that the various NVM devices based on MOSFET structures with the charge storing material made of conducting floating gate, charge trap dielectrics (O/N/O, HfO₂, . . . , etc), or nano-crystals (Si, Ge, . . . , etc), and their fabrication process used herein are for the purpose of description and should not be regarded as limiting. Those of ordinary skill in the art will immediately realize that the embodiment of the present invention described herein in the context of methods and schematics are illustrative only and are not intended to be in any way limiting. Other embodiment of the present invention will readily suggest themselves to such skilled persons having the benefits of this disclosure.

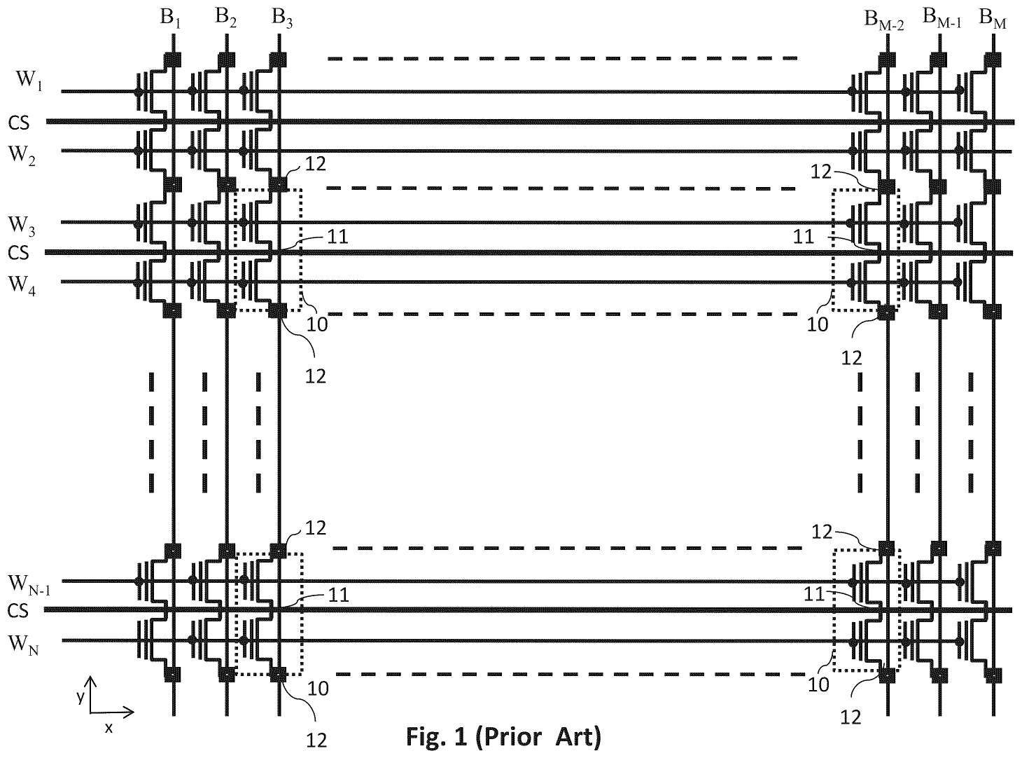

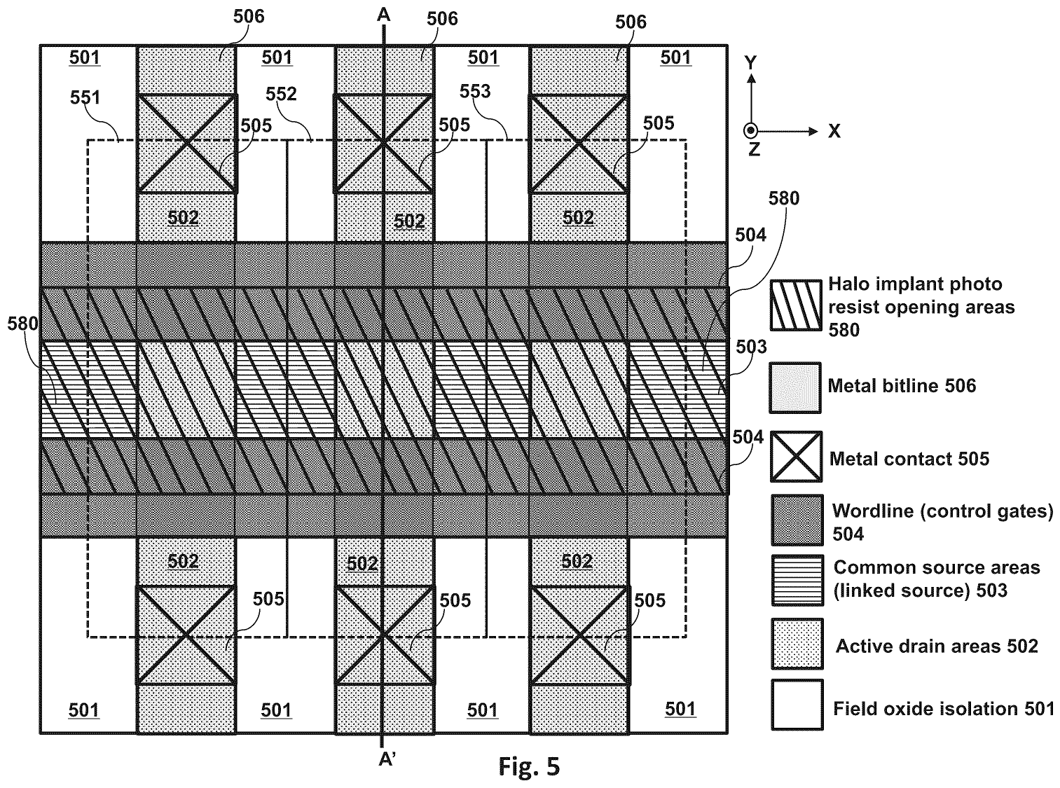

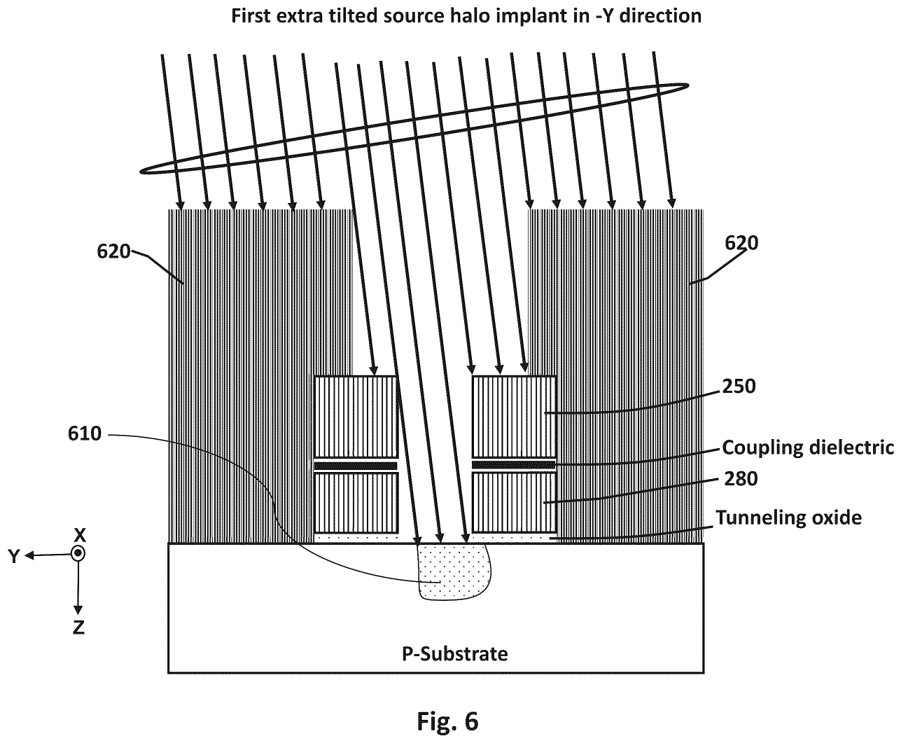

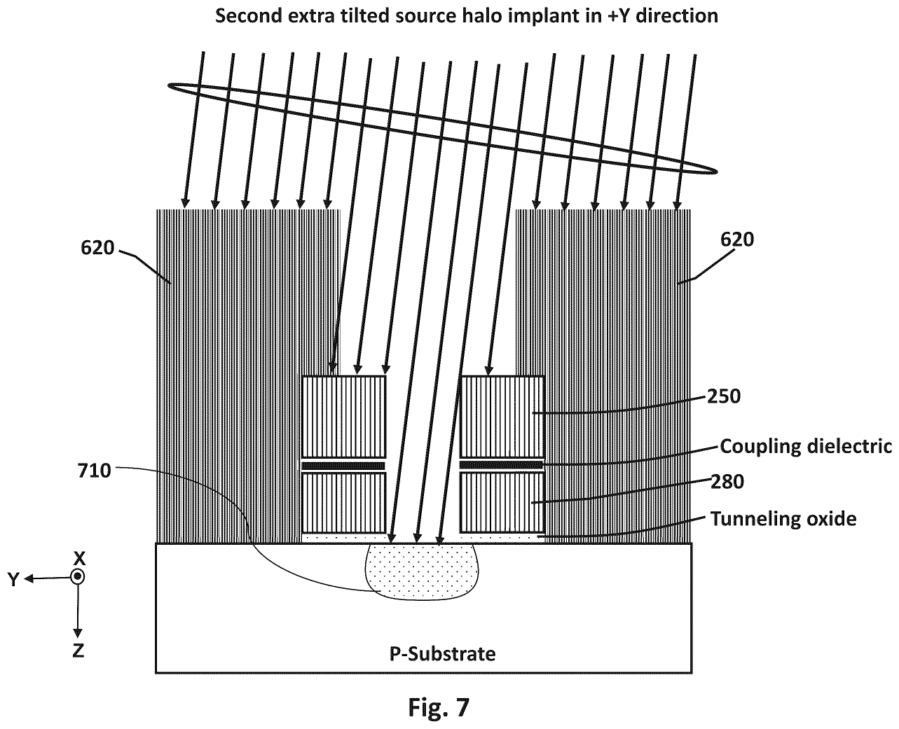

In one embodiment for the illustration purpose, we shall apply the N-type graded channel floating-gate NVM devices for the conventional NOR flash array as the schematic shown in FIG. 1. FIG. 5 shows the top view of the three NOR pairs 551, 552, 553 of the cell devices in the NOR flash array of FIG. 1. The active areas 502 of the NOR pairs are separated by the field oxide isolation 501. Each NOR paired devices (top/down) share the common source areas 503. The drain active areas 502 are connected with the metal contact 505 to the metal bitline 506 along columns of the NVM cells in the vertical direction. A row of control gates of the NVM devices form a wordline 504 in the horizontal direction. The parallel backslash areas 580 containing the common source areas 503 in FIG. 5 are the photo resist openings for performing the extra P-type impurity source tilted halo implants. FIGS. 6 and 7 show the cross section views of the NOR pair of the NVM devices along the cut line AA′ in FIG. 5 after the control gate 250 and the photoresists 620 are formed and before the source and the drain extension implants (not shown) are performed. The first extra source tilted halo implant in the 0° direction (or −Y direction parallel to the gate length direction) (along the cut line AA′ direction) is performed with dosages of impurities of 10¹² cm⁻² to 10¹⁴ cm⁻² to form the implanted P-type impurity distribution region 610 in the common source area 503 in FIG. 6. Then the second extra source tilted halo implant in the 180° direction (or +Y direction parallel to the gate length direction) (along the cut line AA′ direction) is preformed with dosages of impurities of 10¹² cm⁻² to 10¹⁴ cm⁻² to form the final implanted P-type impurity distribution region 710 in the common source areas 503 shown in FIG. 7.

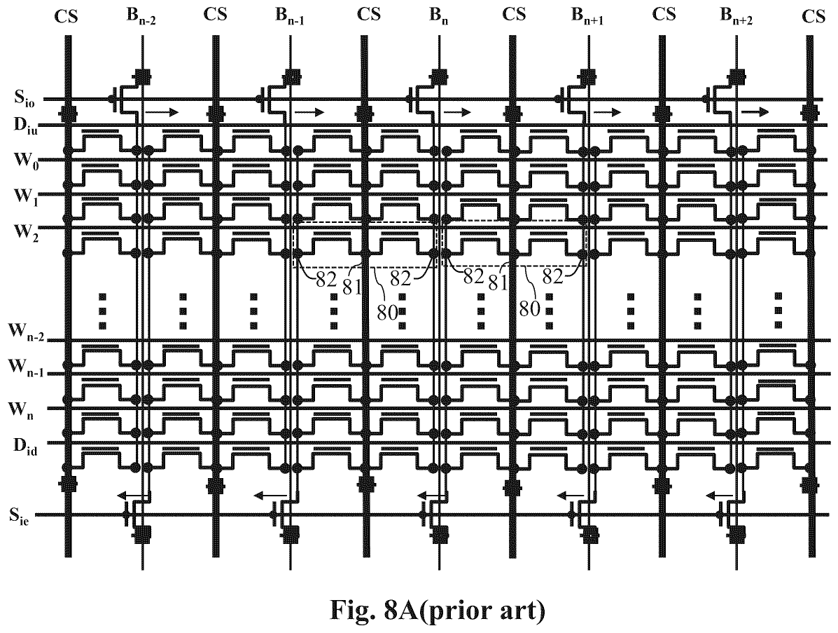

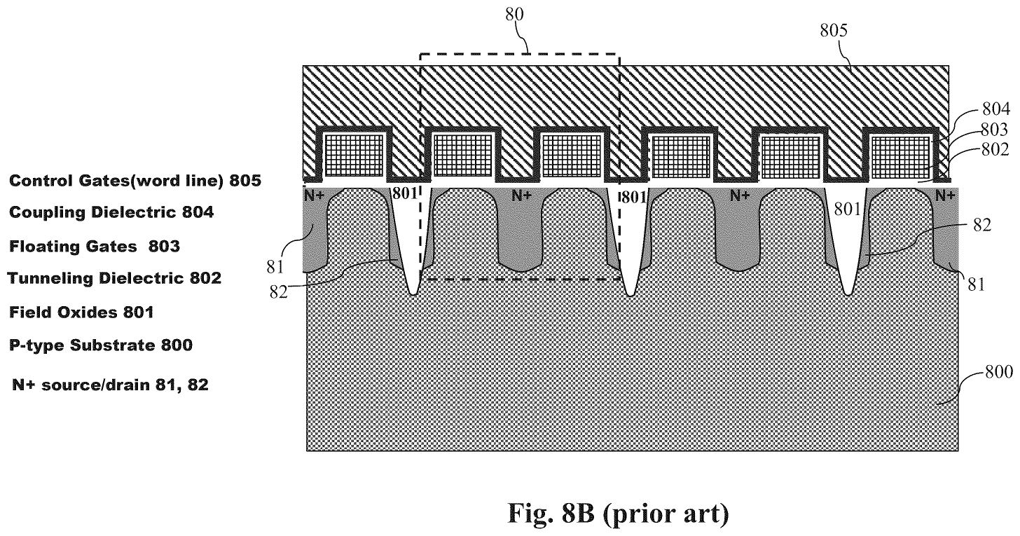

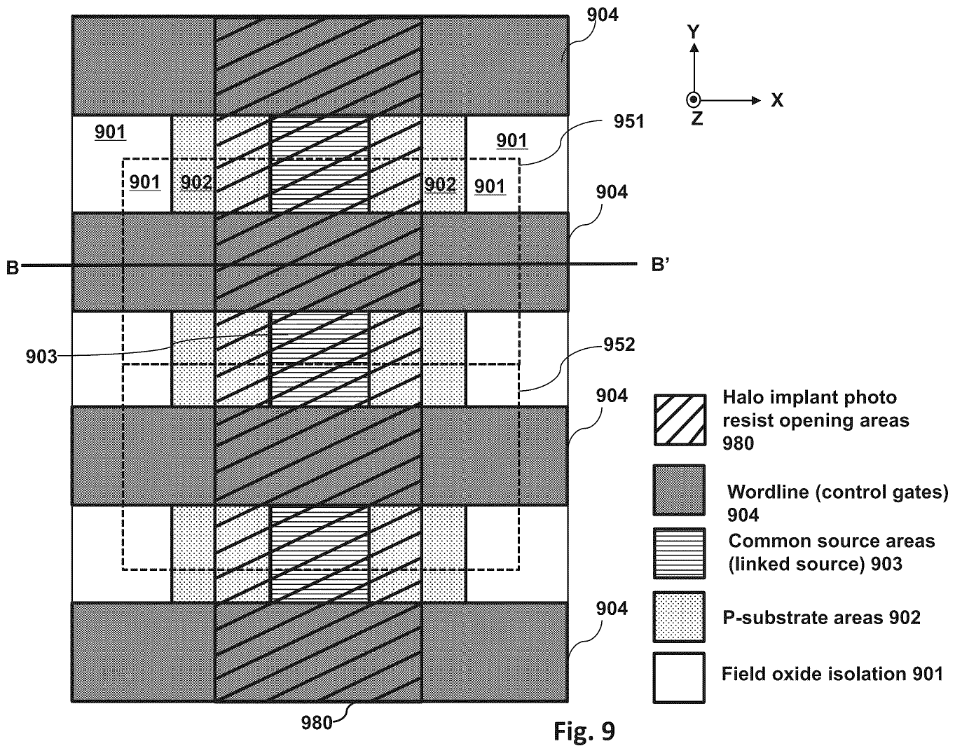

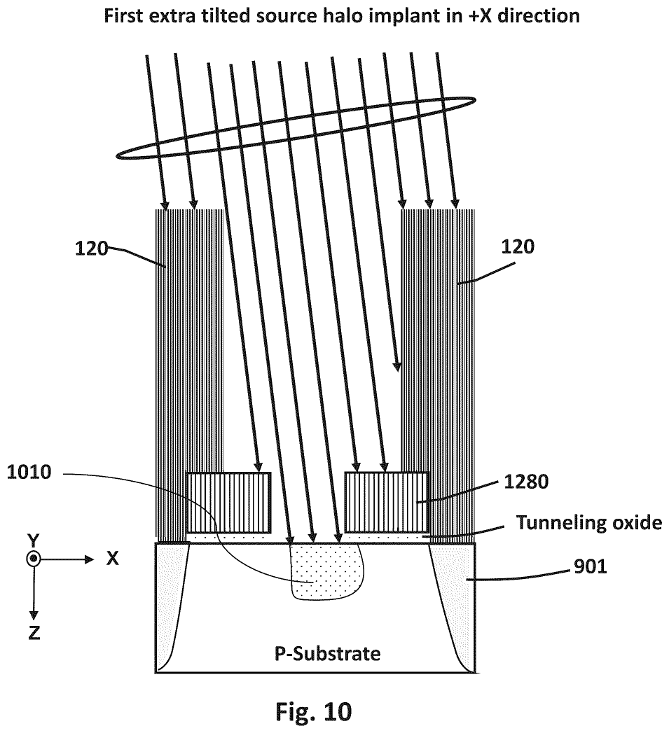

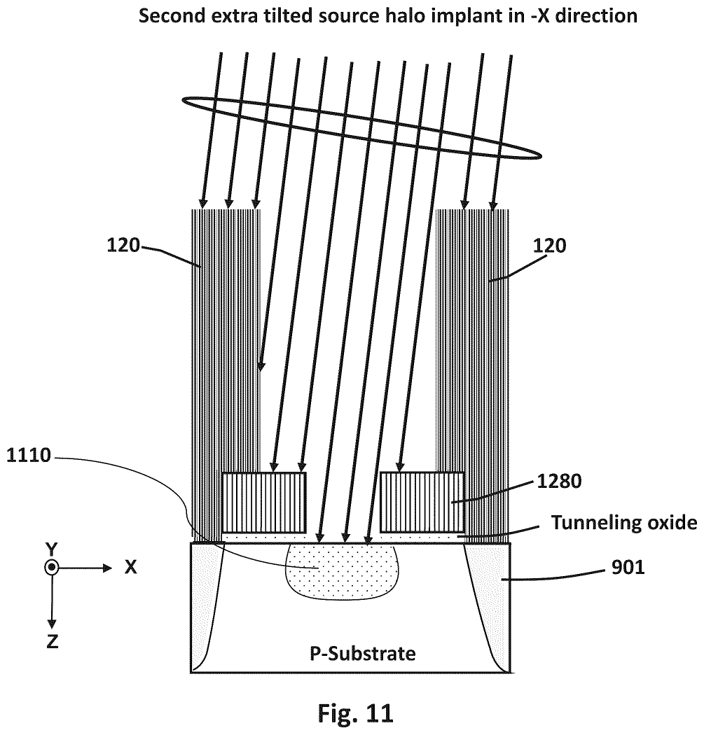

In another embodiment, we apply the N-type graded channel floating-gate NVM devices for the field sub-bitline NOR flash array disclosed in U.S. Pat. No. 9,685,239 as the schematic shown in FIGS. 8A and 8B. Different from the NOR flash array in FIG. 1, the NOR pairs 80 of the NVM cell devices with two field sub-bitline drains 82 and a common source 81 are rotated in 90° along the wordline direction in the conventional field sub-bitline NOR flash array in FIGS. 8A and 8B relative to those along the bitline direction for the conventional NOR flash array in FIG. 1. Referring to FIGS. 8A-8B, every column of NOR cell pair devices 80 are separated by the field oxide areas 801. Each NOR cell pair 80 consists of a common source region 81 linked in the column direction and two N-type drain sub-bitline 82 along the field oxide areas 801 embedded inside the P-substrate area 800 in the column direction. A row of the control gates of the NVM cell devices are connected to form the wordline 805. FIG. 9 shows the top view of a pair of NOR flash memory cell devices 951 and 952 in the field sub-bitline NOR flash array of FIG. 8A. The parallel slash areas 980 containing the common source areas 903 in FIG. 9 are the photoresist openings for performing the P-type impurity extra source titled halo implants. FIGS. 10 and 11 show the cross section views of the NOR pair of the NVM devices along the cut line BB′ in FIG. 9 after the floating gate 1280 and the photoresists 120 are formed and before the source extension region and drain extension regions (not shown) are formed. The first extra source tilted halo implant in the 0° direction (or +X direction parallel to the gate length direction) (along the cut line BB′ direction) is performed with dosages of impurities of 10¹² cm⁻² to 10¹⁴ cm⁻² to form the implanted P-type impurity distribution region 1010 in the common source area 903 shown in FIG. 10. Then the second extra source tilted halo implant in the 180° direction (or −X direction parallel to the gate length direction) (along the cut line BB′ direction) is preformed with dosages of impurities of 10¹² cm⁻² to 10¹⁴ cm⁻² to form the final implanted P-type impurity distribution region 1110 in the common source areas 903 shown in FIG. 11.

The aforementioned description of the preferred embodiment of the invention has been presented for purposes of illustration and description. It is not intended to be exhaustive or to limit the invention to the precise form or to exemplary embodiment disclosed. Accordingly, the description should be regarded as illustrative rather than restrictive. The embodiment is chosen and described in order to best explain the principles of the invention and its best mode practical application, thereby to enable persons skilled in the art to understand the invention for various embodiment and with various modifications as are suited to the particular use or implementation contemplated. It is intended that the scope of the invention be defined by the claims appended hereto and their equivalents in which all terms are meant in their broadest reasonable sense unless otherwise indicated. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiment of the invention. It should be appreciated that variations may be made in the embodiment described by persons skilled in the art without departing from the scope of the present invention as defined by the following claims. Moreover, no element and component in the present disclosure is intended to be dedicated to the public regardless of whether the element or component is explicitly recited in the following claims.

1. A NOR flash memory array formed on a substrate, comprising:
multiple cells organized in rows and columns, each cell comprising a channel region, a charge storing material, a control gate, a source region and a drain region, the cells along a predefined direction being arranged in cell pairs such that each cell pair shares a common source region that is encircled by a source halo implant region;
wherein the source halo implant region has the same conductivity type as the substrate, and the source halo implant region has a higher impurity concentration than a drain side of the channel region; and
wherein when the substrate is grounded, the source region is floating, the drain region is applied with a drain voltage Vd and the control gate is applied with a positive voltage in a selected cell of a selected cell pair, an election injection rate to the charge storing material from the source halo implant region is higher than that from near the drain side of the channel region, where 2V<=Vd<=6V.

2. The memory array according to claim 1, wherein the election injection rate is related to an injection rate of ternary electrons that are generated by first energy transfers from heavy holes accelerated toward the substrate in an electrical field provided by the source halo implant region, and wherein the heavy holes are generated by second energy transfers from surface inverted electrons accelerated in a channel electric field toward the drain region.

3. The memory array according to claim 1, wherein the election injection rate to the charge storing material from the source halo implant region is hundred times to thousand times higher than that from near the drain side of the channel region.

4. The memory array according to claim 1, wherein the higher the impurity concentration in the source halo implant region, the stronger an electrical field generated in the source halo implant region.

5. The memory array according to claim 1, wherein the higher the impurity concentration in the source halo implant region, the higher a device punch-through breakdown voltage for the selected cell.

6. The memory array according to claim 1, wherein the source halo implant region is tilted-implanted with dosages of impurities of 10¹² cm⁻² to 10¹⁴ cm⁻².

7. The memory array according to claim 1, wherein gate lengths of the multiple cells are less than 100 nm.

8. The memory array according to claim 1, wherein the charge storing material is made of one selected from the group consisting of conducting floating gate, charge trap dielectrics and nano-crystals.

9. The memory array according to claim 1, wherein the predefined direction is one of a column direction and a row direction.

10. The memory array according to claim 1, wherein different impurity concentrations distributed along the channel region form a graded channel.

11. A method for forming a NOR flash memory array comprising multiple cells organized in rows and columns, the cells along a predefined direction being arranged in cell pairs such that each cell pair shares a common active area, the method comprising the steps of:
providing multiple isolated structures along the predefined direction, each isolated structure having a charge storing material forming on a substrate;
forming a photoresist film with multiple openings over a surface of the substrate, wherein the openings correspond to the common active areas of the cell pairs;
performing a first tilted halo implant process with dosages of impurities of 10¹² cm⁻² to 10¹⁴ cm⁻² to the common active areas of the cell pairs in a first direction parallel to a gate length direction to form first impurity distribution regions;
performing a second tilted halo implant process with dosages of impurities of 10¹² cm⁻² to 10¹⁴ cm⁻² to the common active areas of the cell pairs in a second direction opposite to the first direction to form second impurity distribution regions so that the first impurity region overlaps the second impurity regions to form multiple source halo implant regions;
forming a common source region inside each source halo implant regions for each cell pair so that the common source region is encircled by a corresponding source halo implant region; and
forming a drain region and a control gate for each cell;
wherein the source halo implant region has the same conductivity type as the substrate, and the source halo implant region has a higher impurity concentration than a drain side of the channel region; and
wherein when the substrate is grounded, the source region is floating, the drain region is applied with a drain voltage Vd and the control gate is applied with a positive voltage in a selected cell of a selected cell pair, an election injection rate to the charge storing material from the source halo implant region is higher than that from near the drain side of the channel region, where 2V<=Vd<=6V.

12. The method according to claim 11, wherein the election injection rate is related to an injection rate of ternary electrons that are generated by first energy transfers from heavy holes accelerated toward the substrate in an electrical field provided by the source halo implant region, and wherein the heavy holes are generated by second energy transfers from surface inverted electrons accelerated in a channel electric field toward the drain region.

13. The method according to claim 11, wherein the election injection rate to the charge storing material from the source halo implant region is hundred times to thousand times higher than that from near the drain side of the channel region.

14. The method according to claim 11, wherein the higher the impurity concentration in the source halo implant region, the stronger an electrical field generated in the source halo implant region.

15. The memory array according to claim 11, wherein the higher the impurity concentration in the source halo implant region, the higher a device punch-through breakdown voltage for the selected cell.

16. The method according to claim 11, wherein gate lengths of the multiple cells are less than 100 nm.

17. The method according to claim 11, herein the charge storing material is made of one selected from the group consisting of conducting floating gate, charge trap dielectrics and nano-crystals.

18. The method according to claim 11, wherein the predefined direction is one of a column direction and a row direction.

19. The method according to claim 11, wherein different impurity concentrations distributed along the channel region form a graded channel.
